(19) United States
(12) Patent Application Publication
(10) Pub. No.: US 2012/0139005 A1
(43) Pub. Date: Jun. 7, 2012

(54) SEMICONDUCTOR DEVICE

(75) Inventors: Takehito IKIMURA, Kanagawa-ken (JP); Rieko Akimoto, Kanagawa-ken (JP); Kiminori Watanabe, Kanagawa-ken (JP); Koji Shirai, Kanagawa-ken (JP); Yasushi Fukai, Kanagawa-ken (JP)

(73) Assignee: Kabushiki Kaisha Toshiba, Tokyo (JP)

(21) Appl. No.: 13/053,123

(22) Filed: Mar. 21, 2011

(30) Foreign Application Priority Data
Dec. 6, 2010 (JP) 2010-271419

(51) Int. Cl. H01L 29/739

(52) U.S. Cl. 257/139; 257/E29.197

(57) ABSTRACT

According to one embodiment, a semiconductor device includes a p-type semiconductor layer, an n-type source region, an insulator, an n-type semiconductor region, an n-type drain region, a p-type channel region, a gate insulating film, a gate electrode, a source electrode, a drain electrode, and an electrode. The source region is provided on a surface of the p-type semiconductor layer. The insulator is provided in a trench formed extending in a thickness direction of the p-type semiconductor layer from the surface of the p-type semiconductor layer. The n-type semiconductor region is provided on the surface of the p-type semiconductor layer between the source region and the insulator. The drain region is provided on the surface of the p-type semiconductor layer between the source region and the n-type semiconductor region and separated from the source region and the n-type semiconductor region. The channel region is provided on the surface of the p-type semiconductor layer between the source region and the drain region and adjacent to the source region and the drain region. The gate insulating film is provided on the channel region. The gate electrode is provided on the gate insulating film. The source electrode is connected to the source region. The drain electrode is connected to the drain region. The electrode is connected to the n-type semiconductor region.

### CROSS-REFERENCE TO RELATED APPLICATIONS

This application is based upon and claims the benefit of priority from the prior Japanese Patent Application No. 2010-271419, filed on Dec. 6, 2010; the entire contents of which are incorporated herein by reference.

### FIELD

Embodiments described herein relate generally to a semiconductor device.

### BACKGROUND

In an integrated circuit in which a drain electrode of an n-type Metal-Oxide-Semiconductor (MOS) transistor mounted on a p-type semiconductor substrate together with a bipolar transistor and the like is used as an output terminal, when an inductive load such as a coil is controlled, for example, a negative potential is given to an output terminal (drain electrode) by a back electromotive force from the inductive load.

As a result, a parasitic n-p-n bipolar transistor in which a p-n junction between an n-type drain region of the n-type MOS transistor and a p-type semiconductor substrate is biased in the forward direction, having an n-type semiconductor region of another element mounted adjacent to or close to the output element (n-type MOS transistor) as a collector, the p-type semiconductor substrate as a base, and the n-type drain region of the n-type MOS transistor as an emitter is operated. Then, there is a concern that a normal operation of another element is disturbed, and the circuit malfunctions.

Hitherto, a measure has been taken in order to suppress the above problem that a distance between the axis of the output element and the axis of another element is increased, but this measure results in an increase of the size of the integrated circuit (die size).

### BRIEF DESCRIPTION OF THE DRAWINGS

FIG. 1A is a schematic cross-sectional view of a semiconductor device of a first embodiment;

FIG. 1B is a schematic cross-sectional view of a semiconductor device of a second embodiment;

FIG. 2A is a schematic cross-sectional view of a semiconductor device of a third embodiment;

FIG. 2B is a schematic cross-sectional view of a semiconductor device of a fourth embodiment;

FIG. 3A is a schematic cross-sectional view of a semiconductor device of a fifth embodiment;

FIG. 3B is a schematic cross-sectional view of a semiconductor device of a sixth embodiment;

FIG. 4A is a schematic cross-sectional view of a semiconductor device of a seventh embodiment;

FIG. 4B is a schematic cross-sectional view of a semiconductor device of a eighth embodiment;

FIG. 5 is a schematic plan view illustrating a plane layout of major elements in a semiconductor device of an embodiment;

FIG. 6 is a schematic plan view illustrating a plane layout of major elements in a semiconductor device of an embodiment; and

FIG. 7 is a circuit diagram of a DC-DC converter.

### DETAILED DESCRIPTION

According to one embodiment, a semiconductor device includes a p-type semiconductor layer, an n-type source region, an insulator, an n-type semiconductor region, an n-type drain region, a p-type channel region, a gate insulating film, a gate electrode, a source electrode, a drain electrode, and an electrode.

The source region is provided on a surface of the p-type semiconductor layer. The insulator is provided in a trench formed extending in a thickness direction of the p-type semiconductor layer from the surface of the p-type semiconductor layer. The n-type semiconductor region is provided on the surface of the p-type semiconductor layer between the source region and the insulator. The drain region is provided on the surface of the p-type semiconductor layer between the source region and the n-type semiconductor region and separated from the source region and the n-type semiconductor region. The channel region is provided on the surface of the p-type semiconductor layer between the source region and the drain region and adjacent to the source region and the drain region. The gate insulating film is provided on the channel region. The gate electrode is provided on the gate insulating film. The source electrode is connected to the source region. The drain electrode is connected to the drain region. The electrode is connected to the n-type semiconductor region.

Exemplary embodiments of the invention will now be described with reference to the drawings. In the following embodiments, similar components in the drawings hereinbelow are marked with like reference numerals.

A semiconductor device of the embodiment uses silicon, for example, as a semiconductor material. Alternatively, a semiconductor other than silicon (a compound semiconductor such as SiC, GaN and the like, for example) may be used.

### First Embodiment

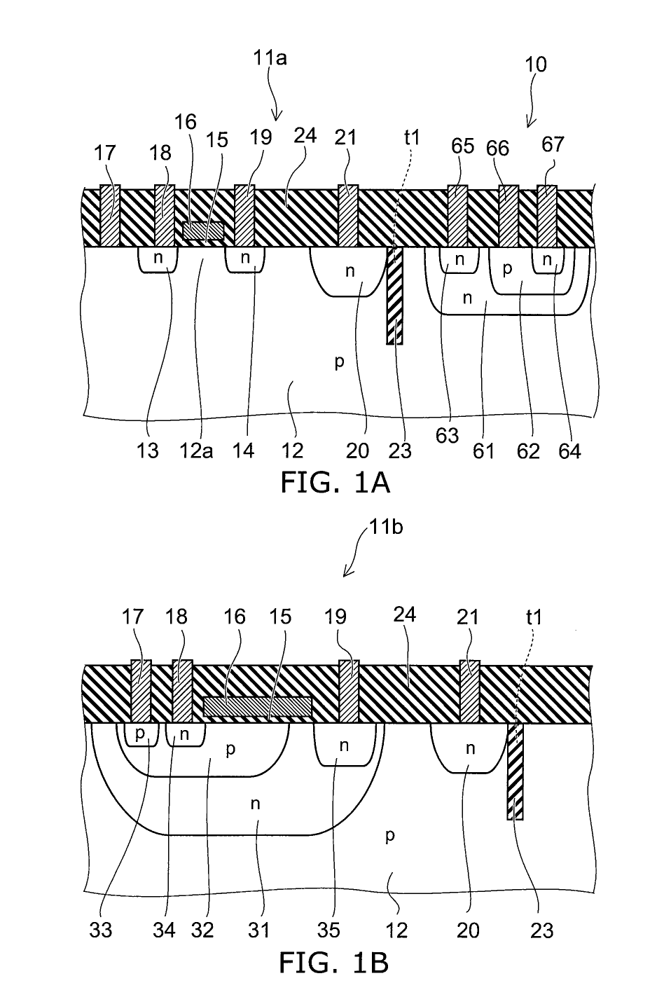

FIG. 1A is a schematic cross-sectional view of a semiconductor of a first embodiment.

The semiconductor device of the embodiment has a structure in which an output element and the other elements are mounted on the same substrate and integrated on a single chip.

FIG. 1A illustrates a structure in which an output element 11a and an n-p-n-type bipolar transistor 10, for example, as the other elements are mounted on a p-type semiconductor layer (or a p-type semiconductor substrate).

The output element 11a and the bipolar transistor 10 are element-separated by a so-called Deep Trench Isolation (DTI) structure. That is, between the output element 11a and the bipolar transistor 10, a trench t1 is formed, and an insulator 23 is embedded within the trench t1. The output element 11a and the other elements, not shown, are also element-separated by the trench t1 and the insulator 23.

The trench t1 extends in the thickness direction of the p-type semiconductor layer 12 from the surface of the p-type semiconductor layer 12. The trench t1 is formed by etching using a Reactive Ion Etching (RIE) method, for example. The insulator 23 includes a silicon oxide, a silicon nitride and the like, for example.

The bipolar transistor 10 has an n-type semiconductor region 61 formed on the surface of the p-type semiconductor layer 12. On the surface of the n-type semiconductor region 61, an n-type collector region 63 and a p-type base region 62 are formed. Moreover, on the surface of the base region 62, an n-type emitter region 64 is formed.

A collector electrode 65 is provided on the collector region 63, and the collector electrode 65 is in ohmic contact with and electrically connected with the collector region 63. A base electrode 66 is provided on the base region 62, and the base electrode 66 is in ohmic contact with and electrically connected with the base region 62. An emitter electrode 67 is provided on the emitter region 64, and the emitter electrode 67 is in ohmic contact with and electrically connected with the emitter region 64.

The output element 11a is an n-type MOS transistor and has an n-type source region 13, an n-type drain region 14, a p-type channel region 12a, a gate insulating film 15, a gate electrode 16, a source electrode 18, a drain electrode 19, a back-gate electrode 17, an n-type semiconductor region 20, and an electrode 21.

The source region 13, the drain region 14, the channel region 12a, and the n-type semiconductor region 20 are formed on the surface of the p-type semiconductor layer 12.

The source region 13 and the drain region 14 are separated from each other. The channel region 12a is provided between the source region 13 and the drain region 14 and is adjacent to the source region 13 and the drain region 14. The drain region 14 is provided between the channel region 12a and the n-type semiconductor region 20.

The n-type semiconductor region 20 is provided between the drain region 14 and the insulator 23. The p-type semiconductor layer 12 is interposed between the drain region 14 and the n-type semiconductor region 20. In FIG. 1A, one of the side faces and the bottom face of the n-type semiconductor region 20 are in contact with the p-type semiconductor layer 12. The other side face of the n-type semiconductor region 20 is adjacent to the insulator 23. Alternatively, the n-type semiconductor region 20 may be separated from the insulator 23.

The trench t1 is deeper than the n-type semiconductor region 20. The insulator 23 extends to a position deeper than the bottom part of the n-type semiconductor region 20. Also, the trench t1 is deeper than the n-type semiconductor region 61 of the bipolar transistor 10. That is, the insulator 23 extends to a position deeper than the bottom part of the n-type semiconductor region 61.

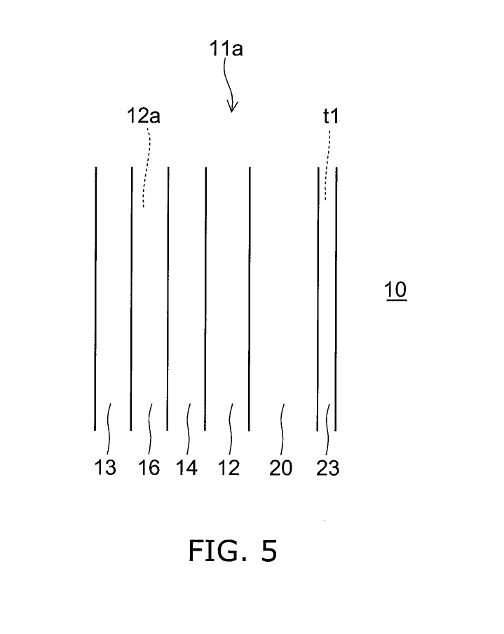

FIG. 5 is a schematic plan view illustrating a plane layout of major elements in the semiconductor device of the embodiment.

The source region 13, the gate electrode 16, the channel region 12a, the drain region 14, the n-type semiconductor region 20, the trench t1, and the insulator 23 are formed in a stripe-state plane layout, for example. The trench t1 and the insulator 23 separate a region on which each element of the output element 11a are formed from a region on which the bipolar transistor 10 is formed.

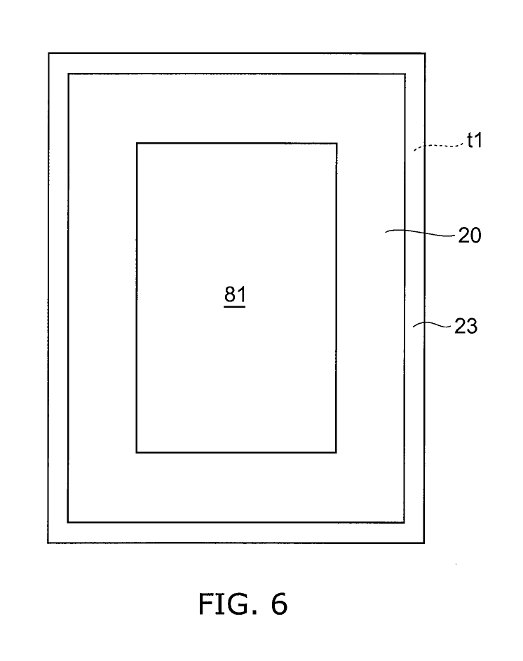

Alternatively, in a layout in which another element is formed around the output element 11a, a layout illustrated in FIG. 6 is effective as a plane layout of the trench t1 and the insulator 23.

That is, the trench t1 and the insulator 23 surround a region 81 including the source region 13, the gate electrode 16, the channel region 12a, the drain region 14, and the n-type semiconductor region 20 of the output element 11a. Outside the region surrounded by the trench t1 and the insulator 23, another element such as the bipolar transistor 10 is formed. The n-type semiconductor region 20 also surrounds the region 81. Therefore, the trench t1 and the insulator 23 surround the region 81 via the n-type semiconductor region 20.

The layout illustrated in FIGS. 5 and 6 can be also applied to other embodiments illustrated in FIGS. 1B to 4B.

The gate insulating film 15 is provided on the channel region 12a, and the gate electrode 16 is provided on the gate insulating film 15.

The source electrode 18 is provided on the source region 13, and the source electrode 18 is in ohmic contact with and electrically connected with the source region 13.

The drain electrode 19 is provided on the drain region 14, and the drain electrode 19 is in ohmic contact with and electrically connected to the drain region 14.

Also, the back-gate electrode 17 is provided on the surface of the p-type semiconductor layer 12. The back-gate electrode 17 is in ohmic contact with the surface of the p-type semiconductor layer 12 at a position on the side opposite to a junction face between the source region 13 and the channel region 12a, for example. A potential equal to the source electrode 18 (a grounding potential, for example), for example, is given to the back-gate electrode 17, and the back-gate electrode 17 stabilizes the potential of the semiconductor layer 12.

The electrode 21 is provided on the n-type semiconductor region 20, and the electrode 21 is in ohmic conduct with and electrically connected to the n-type semiconductor region 20. To the electrode 21, an arbitrary potential between a power-supply potential and the grounding potential given to the integrated circuit (chip) including the above-described elements is given. That is, the electrode 21 is not floating. The power-supply potential does not have to be constant. If the grounding potential is given to the electrode 21, power consumption can be suppressed.

An insulating layer 24 is formed on the surface of the p-type semiconductor layer 12. The insulating layer 24 is also provided between each electrode provided on the p-type semiconductor layer 12 and insulates the electrodes from each other.

In the output element 11a described above, if a desired gate voltage is applied to the gate electrode 16 in a state in which a potential difference is generated between the source electrode 18 and the drain electrode 19, an inversion layer (n-type channel) is formed in the channel region 12a opposed by the gate electrode 16 via the insulating film 15. As a result, an electric current flows between the source electrode 18 and the drain electrode 19 via the source region 13, the inversion layer, and the drain region 14.

Such output element 11a can be used for a low-side switching element of a DC-DC converter, for example.

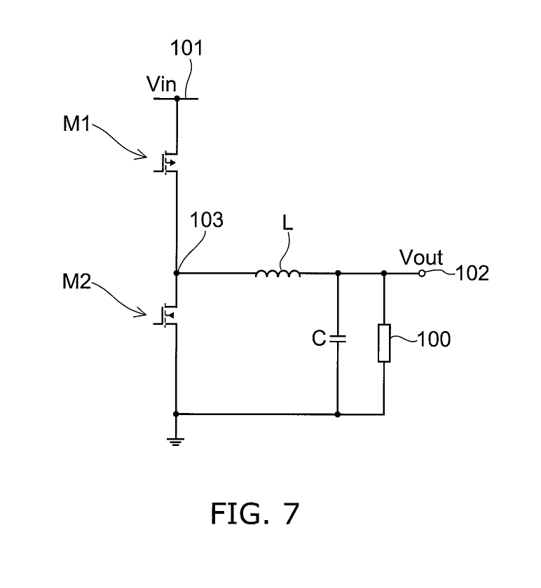

FIG. 7 is a circuit diagram of a DC-DC converter.

This DC-DC converter is provided with a high-side switching element M1, a low-side switching element M2, a coil L, which is an inductive load, and a capacitor C.

This DC-DC converter is a step-down DC-DC converter (buck converter) that outputs an (average) output voltage Vout, which is lower than an input voltage Vin, to a load 100 by alternately turning on/off the high-side switching element M1 and the low-side switching element M2.

Between an input voltage line 101 to which the input voltage Vin is applied and an output terminal 102, the high-side switching element M1 and the coil L are connected in series. The high-side switching element M1 is a p-type MOS transistor, for example, its source electrode is connected to the input voltage line 101, and the drain electrode is connected to the coil L.

The low-side switching element M2 is connected between a connection node 103 between the high-side switching element M1 and the coil L and the ground.

The low-side switching element M2 is the n-type MOS transistor 11a described above by referring to FIG. 1A, and the drain electrode 19 is connected to the drain electrode of the high-side switching element M1 and the coil L, and the source electrode 18 is grounded.

A connection point between the coil L and the output terminal 102 is grounded via a smoothing capacitor C in order to prevent the output voltage from being fluctuated largely in a short time.

To the gate electrode of the high-side switching element M1 and the gate electrode 16 of the low-side switching element M2, a gate driving signal in a substantially inverted phase is supplied.

If the high-side switching element M1 is ON and the low-side switching element M2 is OFF, an electric current is supplied from the input voltage line 101 via the high-side switching element M1 and the coil L to the load 100. At this time, a coil current flowing through the coil L is increased, and energy is accumulated in the coil L.

And if the high-side switching element M1 is turned off and the low-side switching element M2 is turned on, the coil L emits the accumulated energy, and an electric current is supplied from the ground via the low-side switching element M2 and the coil L to the load 100.

If the high-side switching element M1 and the low-side switching element M2 are turned on at the same time, a through current flows from the input voltage line 101 via the high-side switching element M1 and the low-side switching element M2 to the ground. In order to avoid this, in setting a duty of on/off of the high-side switching element M1 and the low-side switching element M2, a dead time during which both the switching elements M1 and M2 are both turned off is set.

As described above, in the output element 11a connected to the inductive load such as a coil L, for example, a negative potential might be given to the output terminal (drain electrode 19) by a back electromotive force from the coil L.

In the embodiment, if a negative potential is applied to the drain electrode 19, a parasitic n-p-n bipolar transistor having the drain region 14 as an emitter, the p-type semiconductor layer 12 as a base, and the n-type semiconductor region 20 as a collector is operated.

The output element 11a of the embodiment is not an element having a double diffusion MOS (DMOS) structure. Therefore, there is no region with high impurity concentration region in the p-type semiconductor layer 12 that becomes the base in the parasitic bipolar transistor. Moreover, the trench t1 and the insulator 23 block a current between the drain region 14 of the output element 11a and the n-type semiconductor region 61 of the bipolar transistor 10, which is another element.

Therefore, the current generated by the operation of the parasitic bipolar transistor flows efficiently between the n-type semiconductor region 20 and the drain region 14. That is, little current is supplied from the n-type semiconductor region 61 of another element (bipolar transistor 10 in FIG. 1A) formed adjacent to or close to the output element 11a. As a result, another element (bipolar transistor 10) is not prevented from operating normally, and malfunction is suppressed.

Also, there is no need to increase an inter-axial distance between the output element 11a and another element (bipolar transistor 10) in order to suppress malfunction of another element, and size reduction of the integrated circuit (die size) is facilitated.

Also, by setting the trench t1 and the insulator 23 deeper than the n-type semiconductor region 20, a current path between the drain region 14 of the output element 11a and the n-type semiconductor region 61 of the bipolar transistor 10 can be made narrow, by which the bipolar transistor 10 is further prevented from malfunctioning.

### Second Embodiment

FIG. 1B is a schematic cross-sectional view of a semiconductor device of a second embodiment.

The semiconductor device of the embodiment also has a structure in which an output element and another element are mounted on the same substrate and integrated on a single chip. FIG. 1B illustrates only an output element 11b, but similarly to the first embodiment illustrated in FIG. 1A, an output element 11b and another element are mounted on the p-type semiconductor layer 12.

The output element 11b and another element are element-separated by the trench t1 and the insulator 23 similarly to the first embodiment.

The output element 11b is an n-type MOS transistor having a double diffusion MOS (DMOS) structure, for example, and has an n-type source region 34, an n-type drain region 31, a p-type channel region 32, an n-type drain contact region 35, a p-type back-gate contact region 33, the gate insulating film 15, the gate electrode 16, the source electrode 18, the drain electrode 19, the back-gate electrode 17, the n-type semiconductor region 20, and the electrode 21.

The drain region 31 is provided on the surface of the p-type semiconductor layer 12. The channel region 32 and the drain contact region 35 are provided separately from each other on the surface of the drain region 31. The source region 34 and the back-gate contact region 33 are provided on the surface of the channel region 32. The source region 34 and the back-gate contact region 33 may be adjacent to each other or may be separated from each other.

The drain contact region 35 has higher n-type impurity concentration than the drain region 31. The back-gate contact region 33 has higher p-type impurity concentration than the channel region 32.

The channel region 32 is provided between the source region 34 and the drain region 31, and the channel region 32 is adjacent to the source region 34 and the drain region 31. The drain region 31 is provided between the channel region 32 and the drain contact region 35, and the drain region 31 is adjacent to the channel region 32 and the drain contact region 35.

The n-type semiconductor region 20 is provided between the drain region 31 and the insulator 23. Between the drain region 31 and the n-type semiconductor region 20, the p-type semiconductor layer 12 is interposed.

The trench t1 is deeper than the n-type semiconductor region 20. That is, the insulator 23 extends to a position deeper than the bottom part of the n-type semiconductor region 20.

The gate insulating film 15 is provided on the channel region 32 between the source region 34 and the drain region 31, and on the gate insulating film 15, the gate electrode 16 is provided.

The source electrode 18 is provided on the source region 34, and the source electrode 18 is in ohmic contact with and electrically connected to the source region 34.

The drain electrode 19 is provided on the drain contact region 35, and the drain electrode 19 is in ohmic contact with and electrically connected to the drain contact region 35. By providing the drain contact region 35 having a relatively high n-type impurity concentration on the surface of the drain region 31, ON resistance can be lowered, and an element area can be reduced.

The back-gate electrode 17 is provided on the back-gate contact region 33. The back-gate electrode 17 is in ohmic contact with the back-gate contact region 33. To the back-gate electrode 17, a potential equal to the source electrode 18 (grounding potential, for example), for example, is given, and the back-gate electrode 17 stabilizes the potential of the channel region 32. By connecting the channel region 32 to the back-gate electrode 17 via the back-gate contact region 33 with a relatively high p-type impurity concentration, the potential of the channel region 32 (back-gate potential) can be further stabilized, and a transistor operation can be stabilized.

The electrode 21 is provided on the n-type semiconductor region 20, and the electrode 21 is in ohmic contact with and electrically connected to the n-type semiconductor region 20. To the electrode 21, an arbitrary potential between the power-supply potential and the grounding potential is given similarly to the first embodiment.

The insulating layer 24 is formed on the surface of the p-type semiconductor layer 12. The insulating layer 24 is also provided between the electrodes provided on the p-type semiconductor layer 12 and insulates the electrodes from each other.

In the output element 11b described above, if a desired gate voltage is applied to the gate electrode 16 in a state in which there is a potential difference between the source electrode 18 and the drain electrode 19, an inversion layer (n-type channel) is formed on the channel region 32 opposed by the gate electrode 16 via the gate insulating film 15. As a result, an electric current flows between the source electrode 18 and the drain electrode 19 via the source region 34, the inversion layer, the drain region 31 and the drain contact region 35, and the ON state is generated.

Also, the output element 11b of the embodiment has a DMOS structure. That is, the drain region 31 with relatively low n-type impurity concentration provided between the drain contact region 35 in ohmic contact with the drain electrode 19 and the channel region 32 functions as a drift region. At a gate-off, the drift region is depleted, which relaxes an electric field, whereby a high breakdown voltage can be obtained. By adjusting the n-type impurity concentration or the horizontal length of the drift region, a desired breakdown voltage can be realized.

Also, if avalanche breakdown occurs, a hole current flows to the back-gate contact electrode 17 via the back-gate contact region 33. As a result, element breakage can be prevented.

The output element 11b of the embodiment can be also used for the low-side switching element of a DC-DC converter, for example. Therefore, in the output element 11b connected to the inductive load such as the coil L, for example, a negative potential might be given by the back electromotive force from the coil L to the output terminal (drain electrode 19).

In the embodiment, if the negative potential is applied to the drain electrode 19, a parasitic bipolar transistor having the drain region 31 also including the drain contact region 35 as an emitter, the p-type semiconductor layer 12 as a base, and the n-type semiconductor region 20 as a collector is operated.

At this time, the trench t1 and the insulator 23 block a current between the drain region 31 of the output element 11b and the n-type semiconductor region of another element.

Therefore, the current generated by the operation of the parasitic bipolar transistor efficiently flows between the n-type semiconductor region 20 and the drain region 31. That is, little current is supplied from the n-type semiconductor region of another element formed adjacent to or close to the output element 11b. As a result, a normal operation of another element is not disturbed, and malfunction is suppressed.

### Third Embodiment

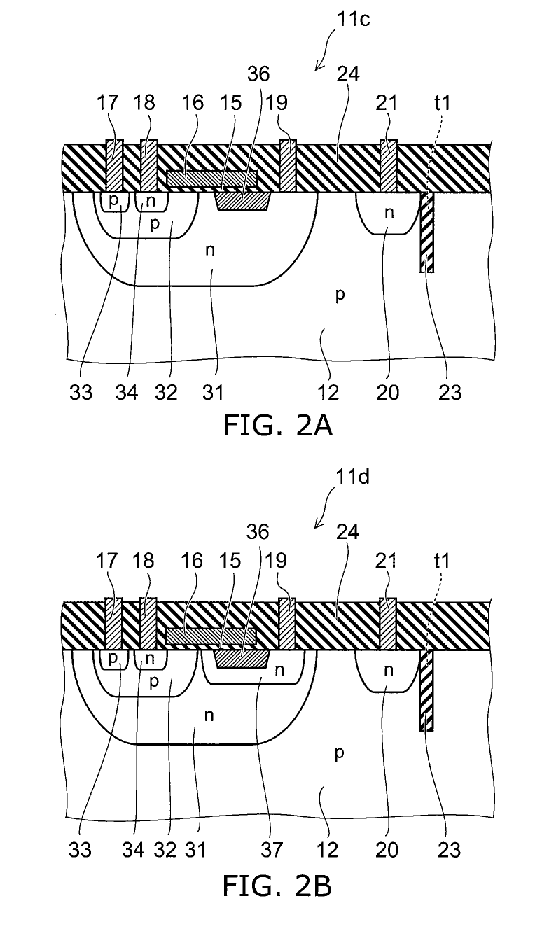

FIG. 2A is a schematic cross-sectional view of a semiconductor device of a third embodiment.

In the embodiment, a field insulating film 36 is provided on the surface of the drain region 31. The other structures are the same as in the second embodiment. Therefore, a normal operation of another element mounted on the same p-type semiconductor layer 12 as an output element 11c of the element is not disturbed, and malfunction is suppressed.

The field insulating film 36 is a silicon oxide film or a silicon nitride film embedded in a trench formed on the surface side of the drain region 31 between the channel region 32 and the drain electrode 19, for example. In the embodiment, a high electric field generated at the end portion on the drain electrode 19 side in the gate electrode 16 can be borne by the field insulating film 36, and thus, a breakdown voltage can be improved.

### Fourth Embodiment

FIG. 2B is a schematic cross-sectional view of a semiconductor device of a fourth embodiment.

In the embodiment, with respect to the structure of the third embodiment, an n-type drain contact region 37 is further provided.

The drain contact region 37 is provided on the surface of the drain region 31 and has a higher n-type impurity concentration than the drain region 31. The drain electrode 19 is in ohmic contact with the drain contact region 37. The field insulating film 36 is provided on the surface of the drain contact region 37 between the channel region 32 and the drain electrode 19.

In the embodiment as well, a normal operation of another element mounted on the same p-type semiconductor layer 12 as an output element 11d is not disturbed, and malfunction is suppressed. Moreover, such transistor characteristics are obtained that the breakdown voltage is high, the ON resistance is low, and the operation is stable.

### Fifth Embodiment

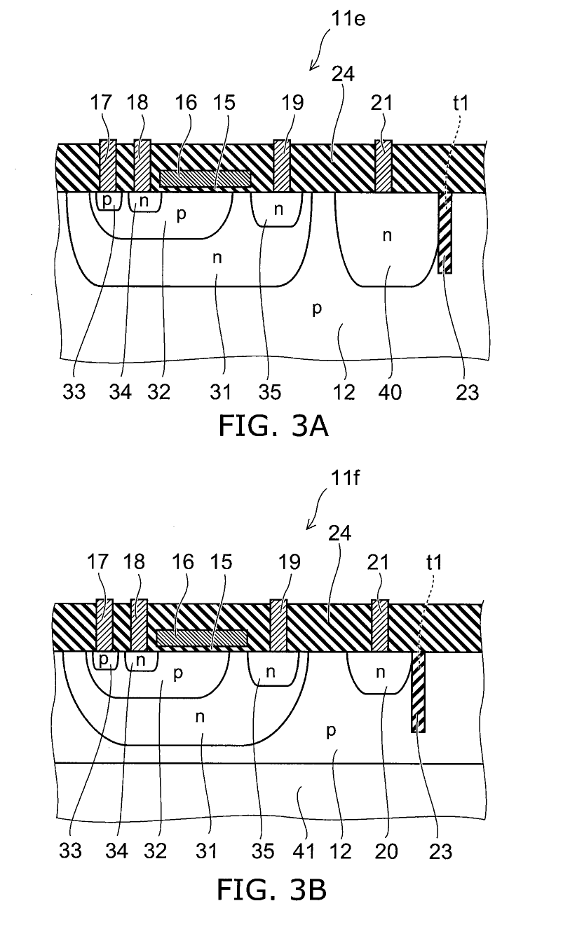

FIG. 3A is a schematic cross-sectional view of a semiconductor device of a fifth embodiment.

In the embodiment, the drain region 31 and an n-type semiconductor region 40 are formed at the same time in the same process. For example, in a region where the drain region 31 is to be formed and a region where the n-type semiconductor region 40 is to be formed in the p-type semiconductor layer 12, n-type impurities are ion-implanted at the same time using a mask, not shown, and then, thermally diffused. Therefore, the drain region 31 and the n-type semiconductor region 40 have the substantially same depth, and peak positions of the respective n-type impurity concentrations are at the substantially same depth. In the embodiment, cost reduction can be realized by decreasing the number of processes.

The electrode 21 is provided on the n-type semiconductor region 40, and the electrode 21 is in ohmic contact with and electrically connected to the n-type semiconductor region 40. To the electrode 21, similarly to the above-described each embodiment, an arbitrary potential between the power-supply potential and the grounding potential is given.

In the embodiment as well, if a negative potential is applied to the drain electrode 19, the parasitic n-p-n bipolar transistor having the drain region 31 also including the drain contact region 35 as an emitter, the p-type semiconductor layer 12 as a base, and the n-type semiconductor region 40 as a collector is operated.

At this time, the trench t1 and the insulator 23 block the current between the drain region 31 of an output element 11e and the n-type semiconductor regions of another element.

Therefore, the current generated by the operation of the parasitic bipolar transistor efficiently flows between the n-type semiconductor region 40 and the drain region 31. That is, little current is supplied from the n-type semiconductor region of another element formed adjacent to or close to the output element 11e. As a result, a normal operation of another element is not disturbed, and malfunction is suppressed.

### Sixth Embodiment

FIG. 3B is a schematic cross-sectional view of a semiconductor device of a sixth embodiment.

The p-type semiconductor layer 12 may be formed by means of epitaxial growth on a substrate 41. That is, the p-type semiconductor layer 12 does not serve as the substrate. By providing the p-type semiconductor layer 12 separately from the substrate 41, integration of various elements on the same substrate 41 is facilitated.

The structure above the substrate 41 is the same as in the second embodiment illustrated in FIG. 1B. That is, in the embodiment as well, a normal operation of another element mounted on the same p-type semiconductor layer 12 as an output element 11f is not disturbed, and malfunction is suppressed.

### Seventh Embodiment

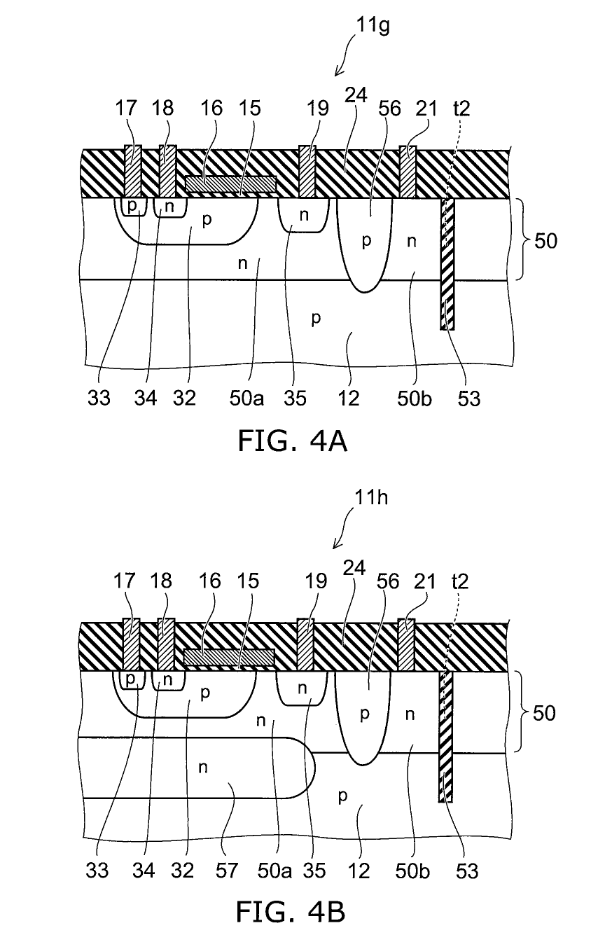

FIG. 4A is a schematic cross-sectional view of a semiconductor device of a seventh embodiment.

In the embodiment as well, a structure in which an output element 11g and another element are mounted on the p-type semiconductor layer 12 is illustrated. The output element 11g and another element are element-separated by a trench t2 and an insulator 53. That is, the trench t2 is formed between the output element 11g and another element, and in the trench t2, the insulator 53 is embedded.

An n-type semiconductor layer 50 is provided on the p-type semiconductor layer 12. On the surface of the n-type semiconductor layer 50, the p-type channel region 32 and the n-type drain contact region 35 are provided. On the surface of the channel region 32, the p-type back-gate contact region 33 and the n-type source region 34 are provided.

Also, the n-type semiconductor layer 50 is divided by a p-type semiconductor region 56. The p-type semiconductor region 56 extends in the thickness direction from the surface of the n-type semiconductor layer 50 and reaches the p-type semiconductor layer 12.

The p-type semiconductor region 56 divides the n-type semiconductor layer 50 into a drain region 50a and an n-type semiconductor region 50b. That is, the p-type semiconductor region 56 is provided between the drain region 50a and the n-type semiconductor region 50b and is adjacent to the drain region 50a and the n-type semiconductor region 50b. The n-type semiconductor region 50b is provided between the p-type semiconductor region 56 and the insulator 53.

The drain contact region 35 is provided on the surface of the drain region 50a between the channel region 32 and the p-type semiconductor region 56. The drain contact region 35 has higher n-type impurity concentration than the drain region 50a. Between the channel region 32 and the drain contact region 35, the drain region 50a having lower n-type impurity concentration than the drain contact region 35 is interposed, and the region functions as a drift region.

The channel region 32 is provided between the drift region and the source region 34, and the channel region 32 is adjacent to the drift region and the source region 34.

The trench t2 penetrates the n-type semiconductor layer 50 and reaches the p-type semiconductor layer 12. The trench t2 is formed by etching using the RIE method, for example. The insulator 53 embedded in the trench t2 contains a silicon oxide and a silicon nitride, for example.

The trench t2 is deeper than the p-type semiconductor region 56 and the n-type semiconductor region 50b. That is, the insulator 53 extends to a position deeper than the bottom parts of the p-type semiconductor region 56 and the n-type semiconductor region 50b.

Similarly to the embodiments described above by referring to FIG. 5, the p-type semiconductor region 56, the n-type semiconductor region 50b, the trench t2 and the insulator 53 are formed in a stripe-state plane layout, for example. That is, the trench t2 and the insulator 53 separate the region where each element of the output element 11g is formed from the region where another element is formed.

Alternatively, as the layout example described above by referring to FIG. 6, the p-type semiconductor region 56, the n-type semiconductor region 50b, the trench t2, and the insulator 53 surround the region including each element of the output element 11g. Outside the region surrounded by the trench t2 and the insulator 53, another element is formed.

The gate insulating film 15 is provided on the channel region 32, and the gate electrode 16 is provided on the gate insulating film 15.

The source electrode 18 is provided on the source region 34, and the source electrode 18 is in ohmic contact with and electrically connected to the source region 34.

The drain electrode 19 is provided on the drain contact region 35, and the drain electrode 19 is in ohmic contact with and electrically connected to the drain contact region 35.

The back-gate electrode 17 is provided on the back-gate contact region 33, and the back-gate electrode 17 is in ohmic contact with the back-gate contact region 33. The same potential as that of the source electrode 18 (a grounding potential, for example), for example, is given to the back-gate electrode 17, and the back-gate electrode 17 stabilizes the potential of the channel region 32.

The electrode 21 is provided on the n-type semiconductor region 50b, and the electrode 21 is in ohmic contact with and electrically connected to the n-type semiconductor region 50b. To the electrode 21, similarly to the above-described embodiments, an arbitrary potential between the power-supply potential and the grounding potential is given.

The insulating layer 24 is formed on the surface of the n-type semiconductor layer 50. The insulating layer 24 is also provided between each electrode provided on the n-type semiconductor layer 50 and insulates the electrodes from each other.

The output element 11g of the embodiment can be also used for the low-side switching element of a DC-DC converter, for example. Therefore, in the output element 11g connected to the inductive load such as the coil L, for example, a negative potential might be given to the output terminal (drain electrode) 19 by the back electromotive force from the coil L.

In the embodiment, if a negative potential is applied to the drain electrode 19, the parasitic n-p-n bipolar transistor having the drain region 50a including the drain contact region 35 as an emitter, the p-type semiconductor region 56 and the p-type semiconductor layer 12 as a base, and the n-type semiconductor region 50b as a collector is operated.

At this time, the trench t2 and the insulator 53 block the current between the drain region 50a of the output element 11g and the n-type semiconductor region of another element.

Therefore, the current generated by the operation of the parasitic bipolar transistor flows efficiently between the n-type semiconductor region 50b and the drain region 50a. That is, little current is supplied from the n-type semiconductor region of another element formed adjacent to or close to the output element 11g. As a result, a normal operation of another element is not disturbed, and malfunction is suppressed.

Also, the n-type semiconductor layer 50 is made to epitaxially grow on the p-type semiconductor layer 12, and a part of the n-type semiconductor layer 50 becomes the drain region 50a. Therefore, it is possible to easily form a drain region deeper than the formation of the drain region using the ion implantation method, and a high breakdown voltage design can be easily realized.

### Eighth Embodiment

FIG. 4B is a schematic cross-sectional view of a semiconductor device of an eighth embodiment.

An output element 11h of the embodiment further has an n-type embedded layer 57 in addition to the structure of the output element 11g of the seventh embodiment illustrated in FIG. 4A. The other structures are the same as those of the seventh embodiment, and the similar advantages can be obtained.

The n-type buried layer 57 is provided between the p-type semiconductor layer 12 and the n-type semiconductor layer 50. The n-type buried layer 57 is provided on the drain region 50a side rather than the p-type semiconductor region 56. That is, the drain region 50a, the channel region 32, the source region 34, and the back-gate contact region 33 are provided on the n-type buried layer 57.

The n-type buried layer 57 has higher n-type impurity concentration than the n-type semiconductor layer 50 and is adjacent to and electrically connected to the drain region 50a. As a result, the elements above the n-type buried layer 57 are separated from the potential of the p-type semiconductor layer 12, which is a substrate. Therefore, the output element and the other various elements can be easily integrated on the same substrate.

According to each of the above-described embodiments, in a use method in which a negative potential is applied to a drain electrode, which is an output terminal of an output element, malfunction of the other elements mounted on the s same substrate as the output element can be suppressed. An application of the output element is not limited to a switching element of a DC-DC converter but the output element of the embodiment can be also used for control of a coil (inductive load) such as a motor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

20

What is claimed is:

1. A semiconductor device, comprising:
a p-type semiconductor layer;
an n-type source region provided on a surface of the p-type semiconductor layer;
an insulator provided in a trench formed extending in a thickness direction of the p-type semiconductor layer from the surface of the p-type semiconductor layer;
an n-type semiconductor region provided on the surface of the p-type semiconductor layer between the source region and the insulator;
an n-type drain region provided on the surface of the p-type semiconductor layer between the source region and the n-type semiconductor region and separated from the source region and the n-type semiconductor region;
a p-type channel region provided on the surface of the p-type semiconductor layer between the source region and the drain region and adjacent to the source region and the drain region;
a gate insulating film provided on the channel region;
a gate electrode provided on the gate insulating film;
a source electrode connected to the source region;
a drain electrode connected to the drain region; and
an electrode connected to the n-type semiconductor region.

2. The device according to claim 1, wherein the trench and the insulator surround a region including the source region, the channel region, the drain region, and the n-type semiconductor region.

3. The device according to claim 1, wherein the n-type semiconductor region surrounds a region including the source region, the channel region, and the drain region.

4. The device according to claim 1, wherein the trench is deeper than the n-type semiconductor region.

5. The device according to claim 1, wherein the channel region is provided on a surface of the drain region, and the source region is provided on a surface of the channel region.

6. The device according to claim 5, wherein the drain region and the n-type semiconductor region have the same depth.

7. The device according to claim 1, wherein a parasitic bipolar transistor having the drain region as an emitter, the p-type semiconductor layer as a base, and the n-type semiconductor region as a collector is operated when a negative potential is applied to the drain electrode.

8. The device according to claim 1, wherein the electrode is grounded.

9. The device according to claim 1, further comprising:
a drain contact region provided on a surface of the drain region and having an n-type impurity concentration higher than an n-type impurity concentration of the drain region,
the drain electrode being in contact with the drain contact region.

10. A semiconductor device, comprising:
a p-type semiconductor layer;
an n-type semiconductor layer provided on the p-type semiconductor layer;
an n-type source region provided on a surface of the n-type semiconductor layer;
an insulator provided in a trench formed extending in a thickness direction of the n-type semiconductor layer from the surface of the n-type semiconductor layer;
a p-type semiconductor region dividing the n-type semiconductor layer between the source region and the insulator and reaching the p-type semiconductor layer.
an n-type semiconductor region provided on the n-type semiconductor layer between the p-type semiconductor region and the insulator;
an n-type drain region provided on the n-type semiconductor layer between the source region and the p-type semiconductor region;
a p-type channel region provided on the surface of the n-type semiconductor layer between the source region and the drain region, adjacent to the drain region and surrounding the source region;
a gate insulating film provided on the channel region;
a gate electrode provided on the gate insulating film;
a source electrode connected to the source region;
a drain electrode connected to the drain region; and
an electrode connected to the n-type semiconductor region.

11. The device according to claim 10, wherein the trench and the insulator surround a region including the source region, the channel region, the drain region, the p-type semiconductor region, and the n-type semiconductor region.

12. The device according to claim 10, wherein the n-type semiconductor region surrounds a region including the source region, the channel region, the drain region, and the p-type semiconductor region.

13. The device according to claim 10, wherein the trench penetrates through the n-type semiconductor layer to reach the p-type semiconductor layer.

14. The device according to claim 10, wherein a parasitic bipolar transistor having the drain region as an emitter, the p-type semiconductor region as a base, and the n-type semiconductor region as a collector is operated when a negative potential is applied to the drain electrode.

15. The device according to claim 10, wherein the electrode is grounded.

16. The device according to claim 10, further comprising:
a drain contact region provided on a surface of the drain region and having an n-type impurity concentration higher than an n-type impurity concentration of the drain region,
the drain electrode being in contact with the drain contact region.

17. The device according to claim 10, further comprising:
an n-type buried layer provided between the p-type semiconductor layer and the n-type semiconductor layer, and having an n-type impurity concentration higher than an n-type impurity concentration of the n-type semiconductor layer,
the drain region, the channel region and the source region being provided on the n-type buried layer.
